(19) United States
(12) Patent Application Publication
(10) Pub. No.: US 2025/0264500 A1
(43) Pub. Date: Aug. 21, 2025

(54) PROBE CARD

(71) Applicant: JAPAN ELECTRONIC MATERIALS CORPORATION, Hyogo (JP)

(72) Inventors: Keiji MATSUOKA, Hyogo (JP); Shingo SATO, Hyogo (JP); Tomoaki INOUE, Hyogo (JP)

(73) Assignee: JAPAN ELECTRONIC MATERIALS CORPORATION, Hyogo (JP)

(21) Appl. No.: 18/847,269

(22) PCT Filed: Jul. 1, 2022
(86) PCT No.: PCT/JP2022/026478

§ 371 Date: Mar. 28, 2025

(51) Int. Cl. G01R 1/073

(52) U.S. Cl. CPC G01R 1/07342

(57) ABSTRACT

[Problem] To prevent a flexible wiring board from peeling off from a substrate.

[Solution] This probe card comprises: a substrate 30 having a flat surface that faces an object 20 to be tested; a flexible wiring board 50 which is composed of an insulating film 51 and has an adhesive surface adhered to the substrate 30 via an adhesive agent 40 and a probe mounting surface on which two or more electrode pads 520 are aligned and arranged at a predetermined interval; and two or more probes 70 respectively disposed on the electrode pads 520. Two or more first anchor pads 521 are respectively formed at positions on the adhesive surface that correspond to the electrode pads 70.

### TECHNICAL FIELD

The present invention relates to a probe card, and more specifically, to an improvement of a probe card equipped with a flexible wiring board.

### BACKGROUND OF THE INVENTION

A probe card is a testing device used for inspecting the electrical characteristics of semiconductor devices formed on a semiconductor wafer. It is equipped with two or more probes on a wiring substrate, with each probe contacting a corresponding electrode formed on the semiconductor wafer. The inspection of the semiconductor device is conducted by bringing the semiconductor wafer close to the probe card, allowing the tips of the probes to contact the electrodes on the wafer, and establishing electrical continuity between the tester device and the semiconductor device through the probes and the wiring substrate.

A probe card with probes mounted on a flexible wiring board has been conventionally known (for example, Patent Literature 1). In the probe card described in Patent Literature 1, the probes are attached to the central lower surface of the flexible wiring board. This flexible wiring board has its peripheral portion fixed by a ring-shaped retaining plate, and the central upper surface is adhered to the top of a truncated quadrangular pyramid-shaped platform mounted on a leaf spring.

### CITATION LIST

### Patent Literatures

[Patent Literature 1] JP 2002-311049 A

### SUMMARY OF THE INVENTION

### Technical Problem

In the case of a probe card where probes are mounted on a flexible wiring board, and the flexible wiring board is adhered to the flat surface of a substrate, there is a risk that the flexible wiring board may detach from the substrate if the adhesive strength is insufficient. For example, when the tip of a probe with a cantilever structure is pressed against the object under inspection, a force that tilts the probe is applied to the base of the probe. Consequently, there is a risk that the flexible wiring board may detach from the substrate at the probe mounting location.

Additionally, variations in the thickness of the adhesive can cause height inconsistencies among the probes, potentially reducing their contact reliability with the object under inspection. Furthermore, when adhering the flexible wiring board, bubbles that form within the adhesive can expand during high-temperature testing and contract during low-temperature testing, leading to a loss of flatness in the flexible wiring board and consequently reducing the contact reliability with the object under inspection.

The present invention has been made in view of the above circumstances and aims to prevent the flexible wiring board from detaching from the substrate in a probe card where the flexible wiring board is adhered to the substrate. Additionally, it aims to improve the contact reliability between the probe card, with the flexible wiring board adhered to the substrate, and the object under inspection. Specifically, it aims to suppress variations in the height of the probes and to prevent the flatness of the electrode pads, where the probes are positioned, from being compromised.

### Solution to the Problem

A probe card according to the first embodiment of the present invention includes a substrate having a flat surface that faces an object under inspection, a flexible wiring board made of an insulating film and having an adhesive surface adhered to the substrate via an adhesive and a probe mounting surface where two or more electrode pads are aligned and arranged at predetermined intervals, and two or more probes, each disposed on a corresponding one of the two or more electrode pads. Wherein two or more first anchor pads are each formed at positions on the adhesive surface corresponding to the two or more electrode pads.

By adopting such a configuration, the first anchor pads are aligned and arranged at predetermined intervals. The first anchor pads are protrusions provided on the adhesive surface of the flexible wiring board, and the spaces between adjacent first anchor pads form recesses. As a result, alternating protrusions and recesses are formed on the adhesive surface of the flexible wiring board, increasing the surface area, which allows the flexible wiring board to be more securely adhered to the substrate. Additionally, since the first anchor pads are formed at positions corresponding to the electrode pads, the flexible wiring board is prevented from detaching from the substrate in the area where the electrode pads are formed, even when the probes elastically deform during testing.

Additionally, excess adhesive on the first anchor pads is accommodated in the recesses, which helps control the thickness of the adhesive layer between the first anchor pads and the substrate. This suppresses variations in the adhesive thickness, reducing height variations among the two or more electrode pads. As a result, height variations among the two or more probes are minimized, improving contact reliability with the object under inspection. Furthermore, by controlling the adhesive thickness, the thermal expansion of bubbles in the adhesive is reduced, preventing the flatness of the electrode pads from being compromised, thereby enhancing contact reliability with the object under inspection.

A probe card according to the second embodiment of the present invention has, in addition to the above configuration, a configuration in which the substrate is a ceramic substrate. The ceramic substrate has a thermal expansion coefficient similar to that of a silicon wafer, making it resistant to warping and ensuring high flatness. Therefore, by adhering a flexible printed circuit board to the ceramic substrate, the contact reliability with the object under inspection can be improved.

A probe card according to the third embodiment of the present invention has, in addition to the above configuration, a configuration in which the electrode pads and the first anchor pads are integrally formed through first through-holes in the insulating film, and the first through-holes are enclosed within outer edges of the electrode pads and the first anchor pads.

By adopting such a configuration, the first anchor pads and the electrode pads are integrally formed, with the insulating film sandwiched between them. This prevents the flexible wiring board from detaching from the substrate due to the first anchor pads separating from the insulating film.

A probe card according to the fourth embodiment of the present invention has, in addition to the above configuration, a configuration in which the first anchor pads have a shape corresponding to the electrode pads.

By adopting such a configuration, the thickness of the adhesive in the region corresponding to the electrode pads can be controlled. This prevents variations in the height of the electrode pads and also prevents the flatness of the electrode pads from being compromised due to the thermal expansion of bubbles in the adhesive.

A probe card according to the fifth embodiment of the present invention, in addition to the above configuration, includes two or more connection pins. Wherein two or more through-holes are aligned and arranged at predetermined intervals in the substrate, each for inserting a corresponding one of the two or more connection pins, two or more second through-holes are formed on the flexible wiring board closer to a peripheral side than the electrode pads, each for inserting a corresponding one of the two or more connection pins, and the electrode pads are electrically connected to the connection pins.

By inserting the connection pins into the through-holes of the substrate and the second through-holes of the flexible wiring board and electrically connecting the connection pins to the probes, the alignment of the flexible wiring board with the substrate is facilitated, and the high-frequency characteristics of the probe wiring can be improved.

A probe card according to the sixth embodiment of the present invention has, in addition to the above configuration, a configuration in which two or more electrode terminals are formed on the flexible wiring board, each surrounding an opening of the two or more second through-holes on the probe mounting surface, the connection pins are connected to the electrode terminals, the electrode terminals are connected to the electrode pads on the flexible wiring board, and second anchor pads are formed at positions on the adhesive surface corresponding to the electrode terminals.

By adopting such a configuration, the second anchor pads are aligned and arranged at predetermined intervals. The second anchor pads are protrusions provided on the adhesive surface of the flexible wiring board, and the spaces between adjacent second anchor pads form recesses. As a result, alternating protrusions and recesses are formed on the adhesive surface of the flexible wiring board, increasing the surface area, which allows the flexible wiring board to be more securely adhered to the substrate.

A probe card according to the seventh embodiment of the present invention has, in addition to the above configuration, a configuration in which the electrode terminals and the second anchor pads are integrally formed through the second through-holes, and the second through-holes are enclosed within outer edges of the electrode terminals and the second anchor pads.

By adopting such a configuration, the second anchor pads and the electrode terminals are integrally formed, with the insulating film sandwiched between them. This prevents the flexible wiring board from detaching from the substrate due to the second anchor pads separating from the insulating film.

A probe card according to the eighth embodiment of the present invention has, in addition to the above configuration, a configuration in which two or more third anchor pads, which do not correspond to either the electrode pads or the electrode terminals, are aligned and arranged at predetermined intervals on the adhesive surface of the flexible wiring board.

By adopting such a configuration, even in regions where neither the electrode pads nor the connection terminals are formed, protrusions and recesses are created on the adhesive surface of the flexible wiring board, allowing it to be securely adhered to the substrate.

### Advantages of the Invention

According to the present invention, in a probe card where the flexible wiring board is adhered to the substrate, it is possible to prevent the flexible wiring board from detaching from the substrate. Additionally, it is possible to improve the contact reliability between the probe card, with the flexible wiring board adhered to the substrate, and the object under inspection. Specifically, it is possible to suppress variations in the height of the probes and to prevent the flatness of the electrode pads, where the probes are positioned, from being compromised.

### BRIEF DESCRIPTION OF DRAWINGS

FIG. 1 is a cross-sectional view showing an example of the schematic configuration of a probe card 100 according to the first embodiment of the present invention.

FIG. 2 is an enlarged cross-sectional view of the main part of the probe card 100 shown in FIG. 1.

FIG. 3 is a view showing an example of the probe mounting surface of the flexible wiring board 50.

FIG. 4 is a view showing an example of the adhesive surface of the flexible wiring board 50.

FIG. 5 is a view showing the adhesive formation region on the adhesive surface of the ceramic substrate 30.

FIG. 6 is a schematic view showing an example of the manufacturing method of the probe card 100 shown in FIG. 1.

FIG. 7 is a cross-sectional view showing an example of the main part configuration of a probe card according to the second embodiment of the present invention.

FIG. 8 is a view showing the adhesive surface of the flexible wiring board 50 according to the third embodiment of the present invention.

FIG. 9 is an enlarged cross-sectional view of the main part of the probe card 100 shown in FIG. 8.

### DETAILED DESCRIPTION OF THE INVENTION

### First Embodiment

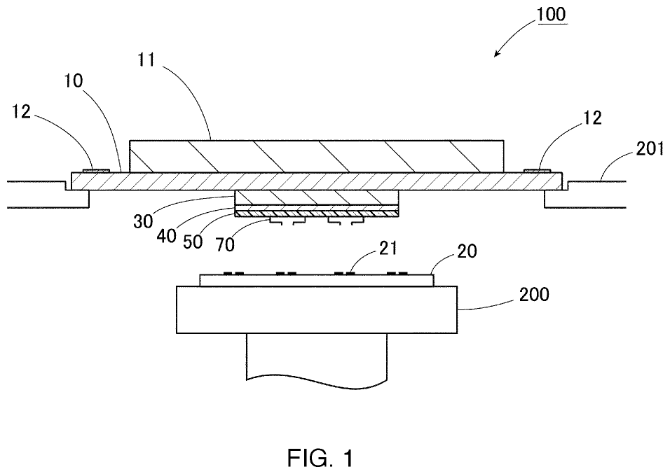

FIG. 1 is a view showing an example of the schematic configuration of a probe card 100 according to the first embodiment of the present invention, and it shows a cross-section of the probe card 100 when cut along a vertical plane. The probe card 100 is mounted on a wafer prober with the probe mounting surface facing downward, positioned opposite to a semiconductor wafer 20 placed on the stage 200. By moving the stage 200 up and down, the probes 70 can be brought into contact with the test electrodes 21 on the semiconductor wafer 20.

The probe card 100 includes a main substrate 10, a reinforcement plate 11, a ceramic substrate 30, an adhesive 40, a flexible wiring board 50, and two or more probes

The main substrate 10 is a wiring board that can be detachably mounted on a wafer prober, and for example, a disc-shaped glass epoxy substrate is used. The main substrate 10 is supported at its peripheral lower surface by the card holder 201 of the wafer prober and is arranged in a substantially horizontal orientation.

A reinforcement plate 11 is attached to the central portion of the upper surface of the main substrate 10 to suppress distortion of the main substrate 10. Additionally, two or more external terminals 12, to which the signal terminals of a tester device (not shown) are connected, are provided at the peripheral portion of the upper surface of the main substrate 10.

The ceramic substrate 30 is a flat ceramic plate attached to the central lower surface of the main substrate 10, serving as a base material to support the flexible wiring board 50. The upper surface of the ceramic substrate 30 is the mounting surface facing the main substrate 10, while the lower surface is a flat adhesive surface where the flexible wiring board 50 is adhered. Ceramic is a material known for its excellent flatness and strength, making it resistant to warping, and it also has superior insulating properties. Additionally, the difference in thermal expansion between ceramic and a silicon wafer is minimal, reducing the likelihood of misalignment during high-temperature testing. For these reasons, ceramic is well-suited as a material for the base supporting the probes 70.

The adhesive 40 forms an adhesive layer between the ceramic substrate 30 and the flexible wiring board 50, bonding the flexible wiring board 50 to the ceramic substrate 30. For the adhesive 40, a thermosetting adhesive, such as an epoxy resin, can be used.

The flexible wiring board 50 is a sheet-like wiring board attached to the adhesive surface of the ceramic substrate 30. The upper surface of the flexible wiring board 50 is the adhesive surface that faces the ceramic substrate 30 via the adhesive 40, while the lower surface is the probe mounting surface where two or more probes 70 are positioned.

The flexible wiring board 50 is a wiring board with a conductive pattern formed on a flexible insulating film and is thinner than the ceramic substrate 30. For example, a flexible printed circuit board using a resin film such as polyimide film can be employed, and a multilayer wiring board composed of multiple resin film layers can also be used.

The resin film, compared to the ceramic substrate 30, allows for easier formation of electrode and wiring patterns and facilitates the production of multilayer substrates, making it possible to manufacture at a lower cost. However, it has a greater difference in thermal expansion rate compared to a silicon wafer and is inferior in terms of flatness and strength. Therefore, by bonding the flexible wiring board 50 to the ceramic substrate 30, it is possible to produce the probe card 100 at a lower cost, while also achieving excellent flatness and strength, and reducing the likelihood of misalignment during high-temperature testing.

The probes 70 are made of an elastically deformable conductive metal, such as NiCo (nickel-cobalt alloy), and have tips for contacting the test electrodes 21 on the semiconductor wafer 20. They are mounted on the probe mounting surface of the flexible substrate. The shape of the probes 70 is arbitrary, and various types such as cantilever-type with a cantilever structure or vertical-type utilizing buckling deformation can be used.

The stage 200 is a platform for placing the semiconductor wafer 20 and is capable of moving and rotating within the horizontal plane, as well as moving in the vertical direction. By horizontally moving or rotating the stage 200, the positions of the tips of the probes 70 can be aligned with the test electrodes 21 on the semiconductor wafer 20. After alignment, by raising the stage 200, the semiconductor wafer 20 can be brought closer to the probe card 100, allowing the tips of the probes 70 to contact the test electrodes 21.

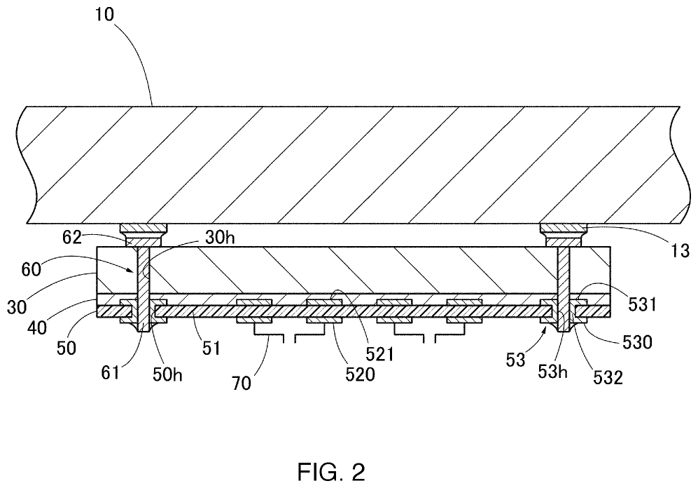

FIG. 2 is an enlarged cross-sectional view of the main part of the probe card 100 shown in FIG. 1, detailing the structure of the main substrate 10, the ceramic substrate 30, and the flexible wiring board 50.

The ceramic substrate 30 has two or more through-holes 30h that penetrate in the thickness direction. A connection pin 60 is inserted into each through-hole 30h, allowing electrical continuity between the main substrate 10 and the flexible wiring board 50.

The internal terminals 13 are electrodes formed on the lower surface of the main substrate 10 and are electrically connected to the external terminals 12 through wiring (not shown) on the main substrate 10. Additionally, the internal terminals 13 are positioned corresponding to the through-holes 30h and are electrically connected to the flexible wiring board 50 via the connection pins 60.

The connection pins 60 are through-electrodes that penetrate the ceramic substrate 30 and include a shaft 61 and an electrode 62, both integrally formed from a conductive metal. The shaft 61 is positioned within the through-hole 30h, with its tip protruding from the lower surface (i.e. adhesive surface) of the ceramic substrate 30. The electrode 62 is wider than the shaft 61 and is secured to the upper surface of the ceramic substrate 30. The electrode 62 faces the internal terminal 13 and is connected to the internal terminal 13 via solder.

The flexible wiring board 50 includes an insulating film 51 that includes two or more electrode pads 520, two or more anchor pads 521, and two or more through-holes 53.

The electrode pads 520 are electrodes for mounting the probes 70 and are formed on the probe mounting surface of the flexible wiring board 50. The electrode pads 520 are arranged to correspond to the test electrodes 21 on the semiconductor wafer 20. Generally, numerous test electrodes 21 are arranged on the semiconductor wafer 20 at predetermined intervals. Therefore, the electrode pads 520 are also aligned and arranged at predetermined intervals.

The anchor pads 521 are protrusions formed on the adhesive surface of the flexible wiring board 50 to prevent the flexible wiring board 50 from detaching from the ceramic substrate 30. The anchor pads 521 do not need to be conductive, but they can be formed as thin films of conductive metal, similar to the electrode pads 520, by utilizing well-known photolithography techniques.

The anchor pads 521 are arranged corresponding to the electrode pads 520. As a result, the protrusions formed by the anchor pads 521 are aligned on the adhesive surface of the flexible wiring board 50. Additionally, by aligning numerous anchor pads 521 at predetermined intervals, recesses are formed between the adjacent electrode pads 520. The anchor pads 521 have a shape corresponding to the electrode pads 520. It is desirable for the outer edge of the electrode pad 520 to match the outer edge of the anchor pad 521. For example, if the anchor pad 521 is symmetrical, it is preferable for the electrode pad 520 to have the same shape as the anchor pad 521. If the anchor pad 521 is asymmetrical, it is desirable for the electrode pad 520 to have an inverted shape as seen from the backside of the anchor pad 521.

Since the adhesive surface of the flexible wiring board 50 is formed as a smooth surface, the addition of the anchor pads 521 creates unevenness, thereby increasing the surface area in contact with the adhesive 40. This enhances the adhesive strength and helps to prevent the flexible wiring board 50 from detaching from the ceramic substrate 30.

When bonding the flexible wiring board 50 to the ceramic substrate 30, any excess adhesive on the anchor pads 521 is accommodated in the recesses between the anchor pads 521. This allows the adhesive layer between the anchor pads 521 and the ceramic substrate 30 to be relatively thinner, while also suppressing the formation of bubbles within the adhesive.

By reducing the thickness of the adhesive, it is possible to minimize variations in the thickness of the adhesive on the anchor pads 521. This helps suppress variations in the height of the electrode pads 520 and consequently reduces variations in the height of the probes 70. Additionally, by suppressing the formation of bubbles, the thermal expansion of bubbles during high-temperature testing and their contraction during low-temperature testing are prevented from compromising the flatness of the flexible wiring board 50. This ensures that the height of the probes 70 remains consistent, and the tips do not shift. Therefore, it becomes possible to reliably bring two or more probes 70 into contact with the object under inspection, improving the contact reliability with the object under inspection.

The through-hole 53 is a hollow through-electrode that penetrates the flexible wiring board 50 in the thickness direction. It is made of a conductive metal, such as copper (Cu), and is formed by plating the through-holes 50h of the flexible wiring board 50. Two or more through-holes 53 are aligned and arranged at predetermined intervals on the flexible wiring board 50. The through-hole 53 includes an electrode terminal 530, an anchor pad 531, and an inner wall conductor 532, forming a through-hole 53h surrounded by the inner wall conductor 532.

The electrode terminal 530 is an electrode formed on the probe mounting surface of the flexible wiring board 50. The electrode terminal 530 is formed to surround the opening of the through-hole 50h and is connected to the electrode pad 520 via a wiring pattern 54 on the flexible wiring board 50.

The anchor pad 531 is a protrusion formed on the adhesive surface of the flexible wiring board 50 to prevent the flexible wiring board 50 from detaching from the ceramic substrate 30. By forming the anchor pad 531, unevenness is created on the adhesive surface, which increases the contact area with the adhesive 40, thereby enhancing the adhesive strength. The anchor pad 531 has a shape corresponding to the electrode terminal 530, for example, the same shape or an inverted shape, and is arranged corresponding to the electrode terminal 530. Here, it is formed to surround the opening of the through-hole 50h.

The inner wall conductor 532 is a thin film formed on the inner wall of the through-hole 50h, connecting the electrode terminal 530 and the anchor pad 531 to each other. Additionally, the through-hole 50h is encompassed within the outer edges of both the electrode terminal 530 and the anchor pad 531. As a result, the insulating film 51 is sandwiched between the interconnected electrode terminal 530 and anchor pad 531, preventing the anchor pad 531 from detaching from the insulating film 51.

The connection pin 60 is inserted into the through-hole 53h of the through-hole 53, soldered to the electrode terminal 530, and electrically connected to the through-hole 53. As a result, the electrode pad 520 is electrically connected to the external terminal 12 via the electrode terminal 530, the connection pin 60, and the internal terminal 13. Using the connection pin 60 for connection helps prevent contact failure due to adhesive contamination or misalignment during bonding. Additionally, it improves high-frequency characteristics.

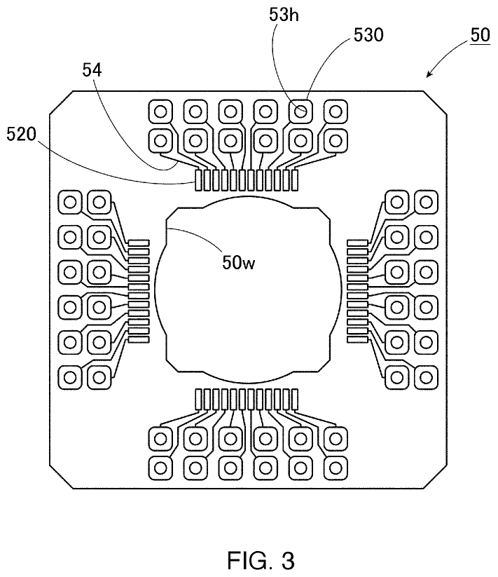

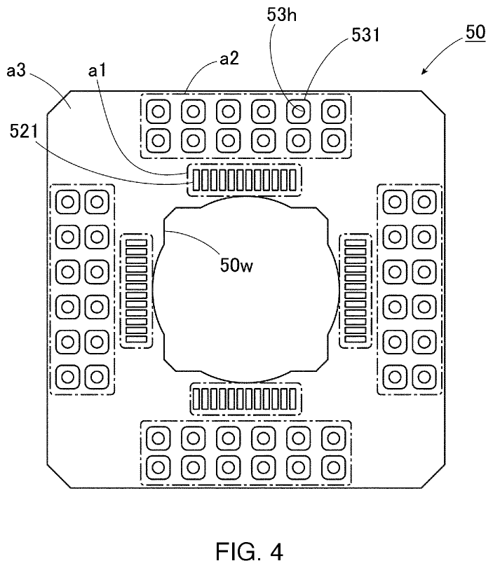

FIGS. 3 and 4 show an example of the flexible wiring board 50 in a plan view, with FIG. 3 illustrating the probe mounting surface and FIG. 4 illustrating the adhesive surface.

The flexible wiring board 50 is provided with an alignment viewing hole 50w in the center. As shown in FIG. 3, the probe mounting surface of the flexible wiring board 50 has electrode pads 520, wiring patterns 54, and electrode terminals 550 formed on it. The electrode pads 520 are aligned near the periphery of the viewing hole 50w along its edge. On the other hand, the electrode terminals 530 are formed near the periphery of the flexible wiring board 50 along its edge. The wiring patterns 54 connect the electrode pads 520 to the electrode terminals 530.

As shown in FIG. 4, anchor pads 521 and 531 are formed on the adhesive surface of the flexible wiring board 50. The anchor pads 521 are aligned and positioned corresponding to the electrode pads 520 shown in FIG. 3, while the anchor pads 531 are aligned and positioned corresponding to the electrode terminals 530.

The regions a1 to a3 in the figure represent areas on the adhesive surface of the flexible wiring board 50. Region a1 is the area where the electrode pads 520 are arranged, region a2 is the area where the electrode terminals 530 are arranged, and region a3 is the area outside of regions a1 and a2. Numerous anchor pads 521 are arranged in region a1, creating an uneven surface. Similarly, numerous anchor pads 531 are arranged in region a2, also creating an uneven surface. While it is preferable for the entire adhesive surface to be bonded to the ceramic substrate 30 via the adhesive 40, at minimum, the first region a1 and the second region a2 should be bonded via the adhesive.

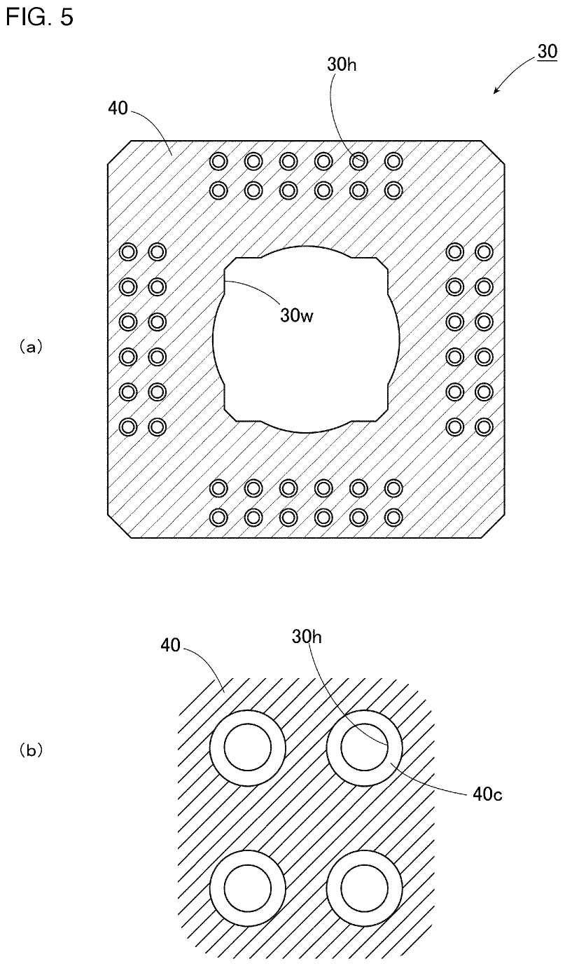

FIG. 5 is a view showing the adhesive layer formation area on the adhesive surface of the ceramic substrate 30. Part (a) of the figure shows the entire adhesive surface of the ceramic substrate 30, and part (b) provides an enlarged view of the vicinity of the through-holes 30h. The ceramic substrate 30 is provided with a viewing hole 30w corresponding to the viewing hole 50w of the flexible wiring board 50. Adhesive 40 is applied to the hatched areas, forming the adhesive layer. While adhesive 40 is formed over the entire adhesive surface of the ceramic substrate 30, designated clearance areas 40c are provided around the through-holes 30h where no adhesive 40 is applied, preventing the adhesive 40 from entering the through-holes 53h.

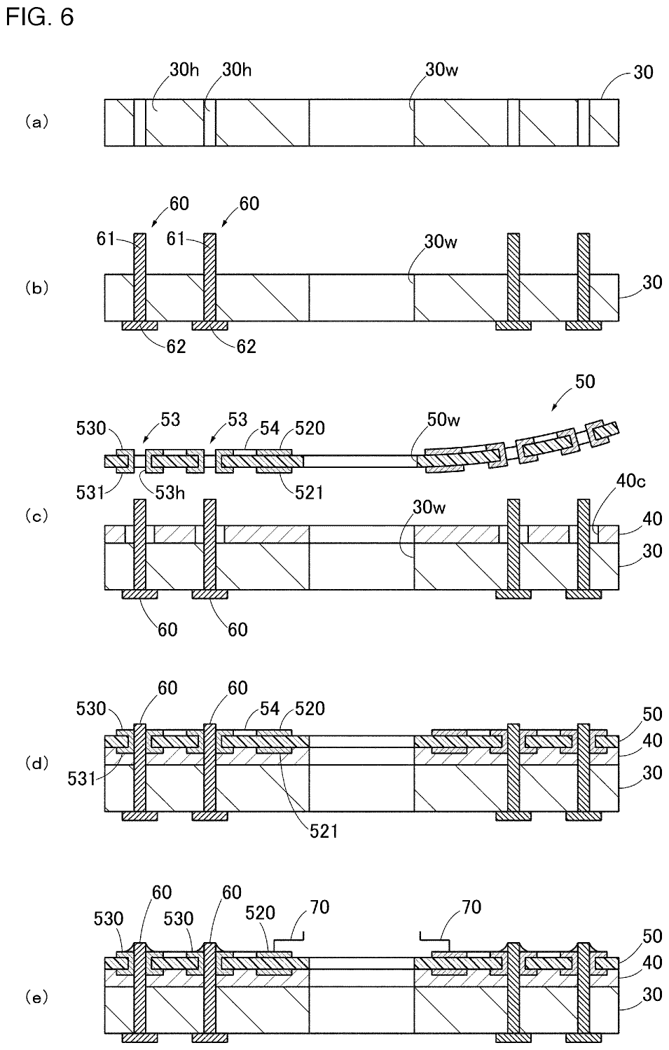

FIG. 6 is a schematic view showing an example of the manufacturing method of the probe card 100 shown in FIG. 1. The ceramic substrate 30 is placed with its adhesive surface facing upward by inverting its vertical orientation.

First, through-holes 30h are formed in the ceramic substrate 30 using a drill (FIG. 6 part (a)). Next, the connection pins 60 are inserted into the through-holes 30h (FIG. 6 part (b)). In this state, the electrodes 62 of the connection pins 60 are in contact with and locked against the mounting surface of the ceramic substrate 30, while the tips of the shafts 61 protrude from the adhesive surface.

Next, an adhesive layer made of adhesive 40 is formed on the adhesive surface of the ceramic substrate 30 (FIG. 6 part (c)), and the flexible wiring board 50 is affixed (FIG. 6 part (d)). The flexible wiring board 50 is aligned so that the connection pins 60 are inserted into the through-holes 53h, and it is placed on the adhesive surface of the ceramic substrate 30. It is then pressed from above to ensure that the adhesive surface adheres closely to the ceramic substrate 30. Afterward, the adhesive 40 is cured by heating, creating a strong bond. Subsequently, the connection pins 60 are soldered to the electrode terminals 530, and the probes 70 are soldered onto the electrode pads 520.

It should be noted that, in this embodiment, the example of forming the adhesive layer on the adhesive surface of the ceramic substrate 30 has been described. However, it goes without saying that, alternatively, the adhesive layer may be formed on the adhesive surface of the flexible wiring board 50.

### Second Embodiment

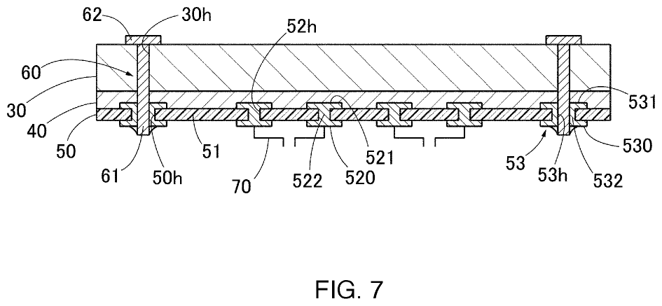

FIG. 7 is a cross-sectional view showing an example of the main part configuration of a probe card 100 according to the second embodiment of the present invention, detailing the structure of the ceramic substrate 30, adhesive 40, and flexible wiring board 50.

The electrode pads 520 and the anchor pads 521 are connected via a through-connection part 522. The through-connection parts 522 are through-electrodes that penetrate the flexible wiring board 50, formed by filling through-holes 52h, which extend through the flexible wiring board 50 in the thickness direction, with a conductive material. For example, after forming the through-holes 52h, the electrode pads 520, anchor pads 521, and through-connection parts 522 are integrally formed by plating the through-holes 52h with a conductive metal such as copper (Cu).

The outer edges of both sides of the through-hole 52h are enclosed within the outer edges of the electrode pads 520 and the anchor pads 521, respectively. As a result, the insulating film 51 is sandwiched between the interconnected electrode pads 520 and anchor pads 521. This configuration prevents the anchor pads 521 from detaching from the flexible wiring board 50 and also prevents the flexible wiring board 50 from detaching from the ceramic substrate 30.

### Third Embodiment

In the first and second embodiments, the example was described where anchor pads 521 are arranged in region a1 and anchor pads 531 are arranged in region a2 on the adhesive surface of the flexible wiring board 50, forming unevenness in these regions a1 and a2. In contrast, this embodiment describes the case where unevenness is also formed in region a3, which is outside of regions a1 and a2.

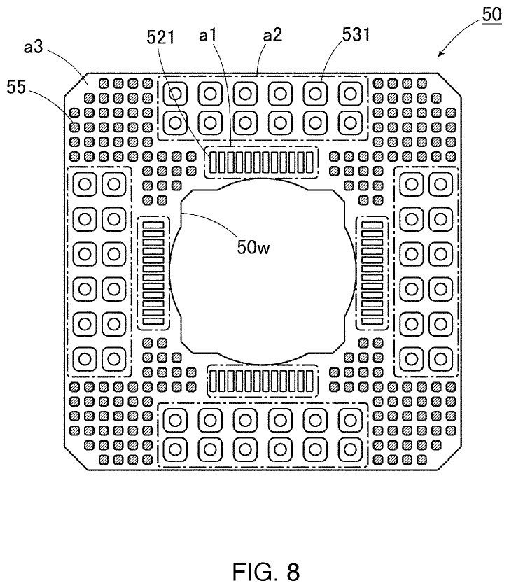

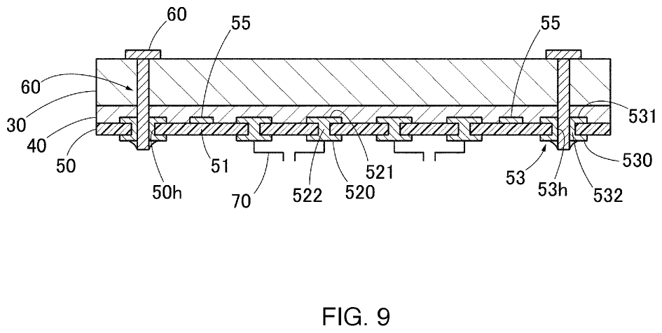

FIGS. 8 and 9 are views showing an example of the main part configuration of a probe card 100 according to the third embodiment of the present invention. FIG. 8 is a view showing an example of the adhesive surface of the flexible wiring board 50 in a plan view, and FIG. 9 is a cross-sectional view showing the detailed structure of the ceramic substrate 30, adhesive 40, and flexible wiring board 50. The probe card in this embodiment differs from the probe cards in FIGS. 4 and 7 in that two or more anchor pads 55 are arranged in region a3. Other configurations remain the same, and redundant explanations are omitted.

The anchor pads 55 are protrusions formed on the adhesive surface of the flexible wiring board 50 to prevent the flexible wiring board 50 from detaching from the ceramic substrate 30. The anchor pads 55 do not need to be conductive, but they can be formed as thin films of conductive metal, similar to the electrode pads 520, by utilizing well-known photolithography techniques.

The anchor pads 55 can take any shape and are aligned at predetermined intervals. As a result, protrusions formed by the anchor pads 55 are arranged in region a3, with recesses formed between the adjacent anchor pads 55. This increases the contact area with the adhesive 40, enhancing the adhesive strength and preventing the flexible wiring board 50 from detaching from the ceramic substrate 30.

### REFERENCE SIGNS LIST

100 Probe card
10 Main substrate
11 Reinforcement plate
12 External terminal
13 Internal terminal
20 Semiconductor wafer
21 Test electrode
30 Ceramic substrate
30h Through-hole
30w Viewing hole
40 Adhesive
40c Clearance area
50 Flexible wiring board
50h Through-hole
50w Viewing hole
51 Insulating film
52h Through-hole
520 Electrode pad
521 Anchor pad
522 Through-connection part
53 Through-hole
530 Electrode terminal
531 Anchor pad
532 Inner wall conductor
53h Through-hole
54 Wiring pattern
55 Anchor pad
60 Connection pin
61 Shaft
62 Electrode
70 Probe
a1-a3 Region

1. A probe card, comprising:
a substrate having a flat surface that faces an object under inspection;
a flexible wiring board made of an insulating film and having an adhesive surface adhered to the substrate via an adhesive and a probe mounting surface where two or more electrode pads are aligned and arranged at predetermined intervals; and
two or more probes, each disposed on a corresponding one of the two or more electrode pads, wherein
two or more first anchor pads are each formed at positions on the adhesive surface corresponding to the two or more electrode pads.

2. The probe card according to claim 1, wherein the substrate is a ceramic substrate.

3. The probe card according to claim 1, wherein
the electrode pads and the first anchor pads are integrally formed through first through-holes in the insulating film, and
the first through-holes are enclosed within outer edges of the electrode pads and the first anchor pads.

4. The probe card according to claim 1, wherein the first anchor pads have a shape corresponding to the electrode pads.

5. The probe card according to any one of claims 1 to 4, further comprising:
two or more connection pins, wherein
two or more through-holes are aligned and arranged at predetermined intervals in the substrate, each for inserting a corresponding one of the two or more connection pins,
two or more second through-holes are formed on the flexible wiring board closer to a peripheral side than the electrode pads, each for inserting a corresponding one of the two or more connection pins, and
the electrode pads are electrically connected to the connection pins.

6. The probe card according to claim 5, wherein
two or more electrode terminals are formed on the flexible wiring board, each surrounding an opening of the two or more second through-holes on the probe mounting surface,
the connection pins are connected to the electrode terminals,
the electrode terminals are connected to the electrode pads on the flexible wiring board, and
second anchor pads are formed at positions on the adhesive surface corresponding to the electrode terminals.

7. The probe card according to claim 6, wherein
the electrode terminals and the second anchor pads are integrally formed through the second through-holes, and
the second through-holes are enclosed within outer edges of the electrode terminals and the second anchor pads.

8. The probe card according to claim 6, wherein two or more third anchor pads, which do not correspond to either the electrode pads or the electrode terminals, are aligned and arranged at predetermined intervals on the adhesive surface of the flexible wiring board.
